(19) United States
(12) Patent Application Publication
(10) Pub. No.: US 2025/0139343 A1
(43) Pub. Date: May 1, 2025

(54) COMPUTER PROGRAM PRODUCT AND METHOD FOR PROCESS VOLTAGE AND TEMPERATURE MARGINING

(71) Applicant: Alliance ATE Consulting Group Inc., Santa Clara, CA (US)

(72) Inventors: William W Wymbs, San Jose, CA (US); Jeff Platt, Dallas, TX (US)

(21) Appl. No.: 18/926,806

(22) Filed: Oct. 25, 2024

Related U.S. Application Data
(60) Provisional application No. 63/593,705, filed on Oct. 27, 2023.

(51) Int. Cl. G06F 30/3308

(52) U.S. Cl. CPC G06F 30/3308

(57) ABSTRACT

A computer-implemented method for validating design of an electronic circuit including receiving, at a processor, a device model defining an electronic circuit; performing, at the processor, logic simulation on the device model with use of a testbench using a set of operating parameters and producing a test vector file of event-based test vectors as a result of the logic simulation; receiving, at the processor, at least one model of the analog test equipment; and converting, at the processor, the test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model.

### CROSS-REFERENCE TO RELATED APPLICATIONS

This application claims the benefit of U.S. Provisional Application Ser. No. 63/593,705 filed Oct. 27, 2023, the contents of which are incorporated herein in its entirety.

### FIELD OF TECHNOLOGY

The present disclosure generally relates to computer-based platforms and/or systems configured for design and testing of electronic circuits.

### BACKGROUND

In the process of developing new electronic circuits, there are two recognized domains: Design and Test. Whereas the design domain relies on simulation of the operation of a new electronic circuit, it is only during physical testing of the manufactured electronic circuit that the performance of the circuit can be validated to meet the desired design requirements. Often there is a need to iterate the process between the Design and Test domains when the manufactured electronic circuit fails to meet the design requirements. The files used in the design process and the files used in the testing process operate in different domains, and there is accordingly a need to convert the domains when converting design files for use with the test equipment and subsequently when providing the testing files back to the design process for redesign or refinement. The domain conversion process is difficult and complicated.

What is needed is a technique to significantly improve the process of domain conversion.

### SUMMARY OF DESCRIBED SUBJECT MATTER

Embodiments of the present disclosure include one or more computer-implemented methods for validating the design of an electronic circuit, including the steps of receiving, at a processor, a device model defining an electronic circuit; performing, at the processor, logic simulation on the device model with use of a testbench using a set of operating parameters and producing a test vector file of event-based test vectors as a result of the logic simulation; receiving, at the processor, at least one model of the analog test equipment; and converting, at the processor, the test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model.

In some embodiments, the operating parameters are input stimuli of the electronic circuit including at least one of voltage, temperature, timing offsets and noise.

In some embodiments, varying one or more of the operating parameters over a range of values includes applying values of a parameter incremented above and below an expected nominal value.

In some embodiments, performing the logic simulation includes creating a VCD (Value Change Dump of Verilog) file as the test vector file.

In some embodiments, the testing patterns are cycle-based, and wherein converting the test vector file includes converting the test vector file to a cycle-based test pattern.

In some embodiments, the device model is represented in Verilog Hardware Description language (HDL).

In some embodiments, the test vector file is one of EVCD, WGL or STIL formats.

In some embodiments, the processor is a single processor or a distributed processor.

In another aspect of the disclosed subject matter a computer-implemented method for validating design of an electronic circuit is described including the steps of: receiving, at a processor, a device model defining an electronic circuit; performing, at the processor, logic simulation on the device model with use of a testbench using a set of operating parameters and producing a first test vector file of event-based test vectors as a result of the logic simulation; receiving, at the processor, at least one model of the analog test equipment; converting, at the processor, the first test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model; executing the test pattern on the physical electronic circuit on the physical testing equipment by running the tester hardware; and converting, at the processor, the test pattern by varying one or more of the operating parameters over a range of values into a second test vector file of event-based test vectors.

In some embodiments, the operating parameters are input stimuli of the electronic circuit including at least one of voltage, temperature, timing offsets and noise.

In some embodiments, varying one or more of the operating parameters over a range of values includes applying values of a parameter incremented above and below an expected nominal value.

In some embodiments, performing the logic simulation includes creating a VCD (Value Change Dump of Verilog) file as the test vector file.

In some embodiments, the testing patterns are cycle-based, and wherein converting the test vector file includes converting the test vector file to a cycle-based test pattern.

In some embodiments, the device model is represented in Verilog Hardware Description language (HDL).

In some embodiments, the test vector file is one of EVCD, WGL or STIL formats.

In some embodiments, the processor is a single processor or a distributed processor.

In some embodiments, after executing the test pattern, the method further includes comparing an observed output from the physical electronic circuit with an expected output from the test pattern.

In some embodiments, the computer-implemented method further includes identifying defects in the operation of the electronic circuit.

In a further aspect of the disclosed subject matter, a computer program product for validating design of an electronic circuit is provided, the computer program product including a computer readable medium tangibly embodying non-transitory computer-executable program instructions thereon that, when executed, cause one or more computing devices to: receive a device model defining an electronic circuit; perform logic simulation on the device model with use of a testbench using a set of operating parameters and producing a first test vector file of event-based test vectors as a result of the logic simulation; receive at least one model of the analog test equipment; and convert the first test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced by using the device model.

In some embodiments, the non-transitory computer-executable program instructions, when executed, further cause one or more computing devices to convert the test pattern by varying one or more of the operating parameters over a range of values into a second test vector file of event-based test vectors.

### BRIEF DESCRIPTION OF THE DRAWINGS

FIG. 1 is a block diagram of a flowchart of an illustrative methodology for simulation of an electronic circuit, chip, or module by use of a simulator module.

FIG. 2 is a flowchart of an illustrative methodology for the conversion of the output results parameter set, e.g., a test vector file, by the use of a domain conversion module to generate a test pattern for testing the electronic circuit on ATE.

FIG. 3 is a flowchart of an illustrative methodology for simulation of an electronic circuit to derive simulation output results and conversion of simulation output results by the use of a conversion module to a test pattern for testing the electronic circuit.

FIG. 4 illustrates a flowchart of an illustrative methodology for a conversion of the testing pattern to a test vector file by the use of a domain conversion module.

FIG. 5 illustrates a flowchart of an illustrative methodology for a further re-simulation of an electronic circuit, chip, or module by use of a simulator module.

FIG. 6 is a block diagram of a flowchart of an illustrative methodology for simulation of an electronic circuit, chip, or module by use of a simulator module.

FIG. 7 is a flowchart of an illustrative methodology for the conversion of the output results parameter set, e.g., a test vector file, by the use of a PVT domain conversion (PVT DC) module in accordance with the disclosed subject matter to generate a test pattern for testing the electronic circuit on a physical electronic circuit produced using the device model.

FIG. 8 is a flowchart of an illustrative methodology for simulation of an electronic circuit to derive simulation output results and conversion of simulation output results by the use of a PVT DC module to a test pattern for testing the electronic circuit.

FIG. 9 illustrates a flowchart of an illustrative methodology for a conversion of the testing pattern to a test vector file by the use of a PVT DC module.

FIG. 10 illustrates a flowchart of an illustrative methodology for a further re-simulation of an electronic circuit, chip, or module by use of a simulator module.

FIG. 11 illustrates a flowchart of an illustrative methodology for a conversion of the testing pattern to a test vector file by the use of a PVT DC module.

FIG. 12 illustrates a flowchart of an illustrative methodology for margining a base simulation simultaneously for both domains using PVTX parameter setting.

### DETAILED DESCRIPTION

Various detailed embodiments of the present disclosure, taken in conjunction with the accompanying figures, are disclosed herein; however, it is to be understood that the disclosed embodiments are merely illustrative. In addition, each of the examples given in connection with the various embodiments of the present disclosure is intended to be illustrative, and not restrictive.

Throughout the specification, the following terms take the meanings explicitly associated herein, unless the context clearly dictates otherwise. The phrases “in one embodiment” and “in some embodiments” as used herein do not necessarily refer to the same embodiment(s), though it may. Furthermore, the phrases “in another embodiment” and “in some other embodiments” as used herein do not necessarily refer to a different embodiment, although it may. Thus, as described below, various embodiments may be readily combined, without departing from the scope or spirit of the present disclosure.

In addition, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the terms “and” and “or” may be used interchangeably to refer to a set of items in both the conjunctive and disjunctive in order to encompass the full description of combinations and alternatives of the items. By way of example, a set of items may be listed with the disjunctive “or”, or with the conjunction “and.” In either case, the set is to be interpreted as meaning each of the items singularly as alternatives, as well as any combination of the listed items.

A computer product and process is described herein that simultaneously or serially margins Process, Voltage and Temperature (PVT) parameters during the domain conversion/translation of design files to ATE (Automated Test Equipment) files and the back-annotated files to Verilog/STIL TBs for re-simulation without the need of ATE simulation/emulation models. Both Design and Test will reflect the new margined conditions.

Margins are specified in a file that overrides the original/existing setup parameters to a new min/max or user-definable values. This creates the stress conditions/margins for a device using the conversion process between domains. Margined parameters include voltage, temperature, timing offsets and noise. Applying the margin can include varying one or more of the operating parameters over a range of values includes applying values of a parameter incremented above and below an expected nominal value. This can be done simultaneously, in a one-step process for both domains or serially in a 2-step process. In both cases the margining is done during the domain conversion process. The end result is a margined Test Bench that will be re-simulated that has the ATE information encoded in it on how the Silicon and Test equipment (ATE) will execute together in the hardware/silicon environment.

The margin is applied as part of the domain conversion process between both domains. If the margined test benches pass re-simulation, then the same ATE setups will pass on silicon over the margined region. This process enables full automation and eliminates the complex and manual margining in the individual domains with complex GUI tools and/or ATE HDL models or emulators.

The key component of the design margined Test Bench contains, has encoded in it, exactly how the ATE margin files will execute on hardware with silicon. This establishes a direct link between the two domains at the margin condition. It is important to note the base simulation used in the conversion that the margins are applied to, creates a new test bench that has the ATE information encoded and does not require an ATE HDL model or emulator.

This technique significantly reduces the number of re-simulations and time needed to characterized how ATE systems will affect simulations before silicon arrive.

Simulations can take days or even weeks to run. The PVT margin process described herein can take an existing simulation result and create a new margined setup for both design and ATE in minutes to hours. The design does not need to be re-simulation to generate the ATE setups. Additionally, the HDL Model does not need to interact with a complex HDL ATE Model or Emulator to generate the margins.

The computer product and process described herein enables developers of integrated circuits to analyze/margin their silicon before it returns from fabrication with ATE equivalent simulations (REPLAY). A simulation can take days or weeks to run, so margin during conversion saves tremendous time. Typically, this margin is performed with silicon that arrives in the Test domain. In order to run on the ATE (Test) with the margin parameters and ranges, such changes must be done manually in the GUI tools of the ATE system. It enables companies to predict how the chip will respond so it can be immediately/quickly release a chip into production without the complicated manual back and forth between design and test.

Simulations can take days or weeks to simulate a single PVT parameter group. This simulation is required for tools to convert a fixed setup to ATE. The computer product and process described herein can in minutes to hours create multiple/different margin setup by taking the original setup-simulation and skew/margin specified parameters bypassing a required simulation to get the margins. An infinite number of margin setting can be generated from a base simulation thru the conversion process significantly improving the process efficiency.

The process includes creating the ATE files with the desired margins applied, using a Verilog Test Bench to re-simulate with the margins, and generating an expected simulation result (EVCD) predicting the re-simulation results.

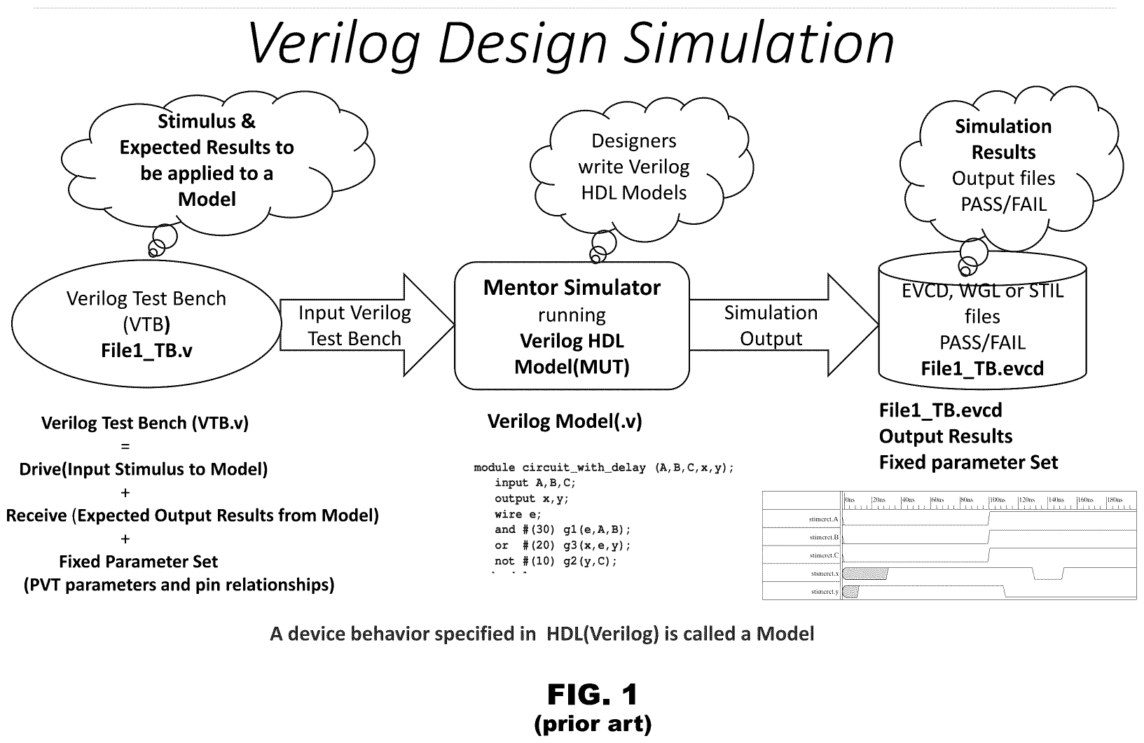

The legacy process uses design files that represent a fixed set of parameters that are manually margined with the Test equipment GUI tools to capture a set of margin parameters. Then the results are manually entered into the GUI in the design domain or point-to-point (fixed) translated back to see if they can achieve correlation as to why results may not as be expected on silicon. The legacy process is further illustrated in FIGS. 1-5.

FIG. 1 is a block diagram of a flowchart of an illustrative methodology for simulation of an electronic circuit, chip, or module by use of a simulator module. In some embodiments, Verilog Hardware Description language (HDL) is used to describe the behavior of an integrated circuit, chip, or module in software. Verilog Test Bench (VTB) is a subset of the Verilog Language used to apply stimulus (inputs) and compare results (outputs) of a Verilog Model running in a simulator (e.g., Mentor, Synopsys, Cadence) A simulator module is a software environment where a Verilog HDL Model (MUT) can be run by applying Test Benches (e.g., time stamp actions representing drives and compares in sequential time on pins: CLK 1@ #10 ns, CLK 0@ #21 ns). The simulation output results (typically expressed in an .evcd, .wgl. or .stil file) predicts the operation of the circuit under a fixed parameter set and whether it meets desired operation characteristics, e.g., a “pass” or a “fail.” The simulation module is run using a fixed parameter set, sometimes referred to as PVTM for process, voltage, temperature, timing or other parameters.

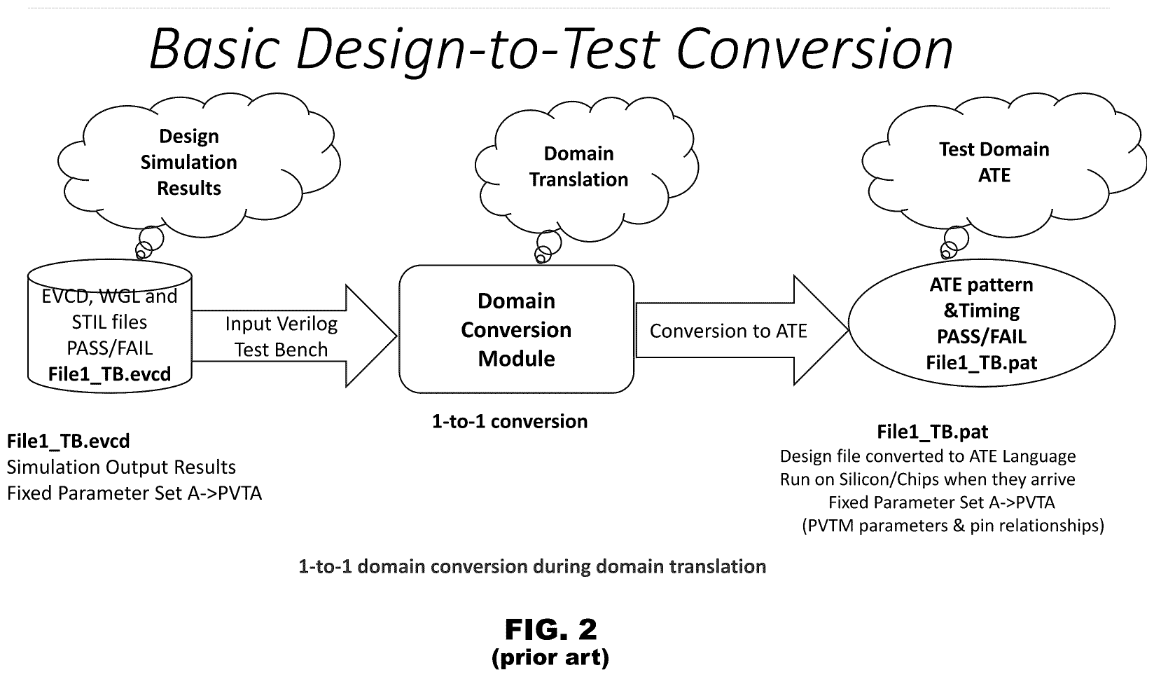

FIG. 2 is a flowchart of an illustrative methodology for the conversion of the output results parameter set, e.g., a test vector file, by the use of a domain conversion module to generate a test pattern for testing the electronic circuit on ATE. ATE is the physical equipment that drives real electrical signals into the electronic circuits manufactured according to the design parameters in order to validate output responses in the silicon chips. The physical electronic circuit/chip being tested is often referred to as a Device Under Test (DUT). The ATE testing procedures are typically running in the time domain (TD), e.g., events happening in real time. ATE Domain (ATED) is based on a cycle count that increments linearly. Each cycle can have formatted drive and receive actions during its period (e.g., one cycle). It has a custom language describing a test pattern that defines how to drive inputs on the physical DUT. The domain conversion module performs a 1-to-1 conversion from the simulation output results to obtain an ATE testing pattern in the ATE language. Once the ATE testing pattern is obtained, the DUT is tested on the ATE to determine whether the DUT, when manufactured using real-world processes, operates as predicted by the design.

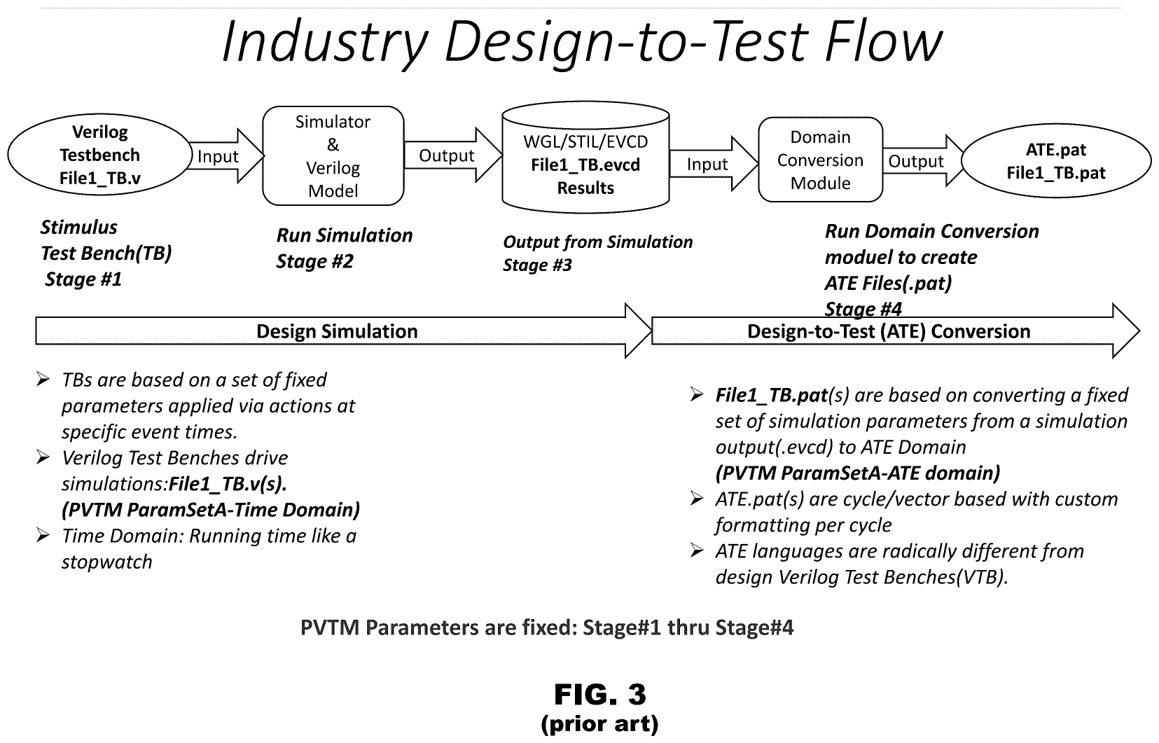

FIG. 3 is a flowchart of an illustrative methodology for simulation of an electronic circuit to derive simulation output results and conversion of simulation output results by the use of a conversion module to a test pattern for testing the electronic circuit. FIG. 3 captures the processes described above in FIGS. 1 and 2 in a sequence. The stimulus test bench (TB) is based on a set of fixed parameters applied via actions at specific event times. The Verilog TB(s) drive simulations: File1_TB.v(s). The ATE test pattern (e.g., File1_TB.pat) generated by the domain conversion module is derived by converting a fixed set of simulation parameters from a simulation output (.evcd, .wgl. or .stil file) to ATE Domain (PVTM ParamSetA-ATE domain) The ATE.pat files are cycle/vector based with custom formatting per cycle. The ATE languages are radically different from design Verilog Test Benches (VTB).

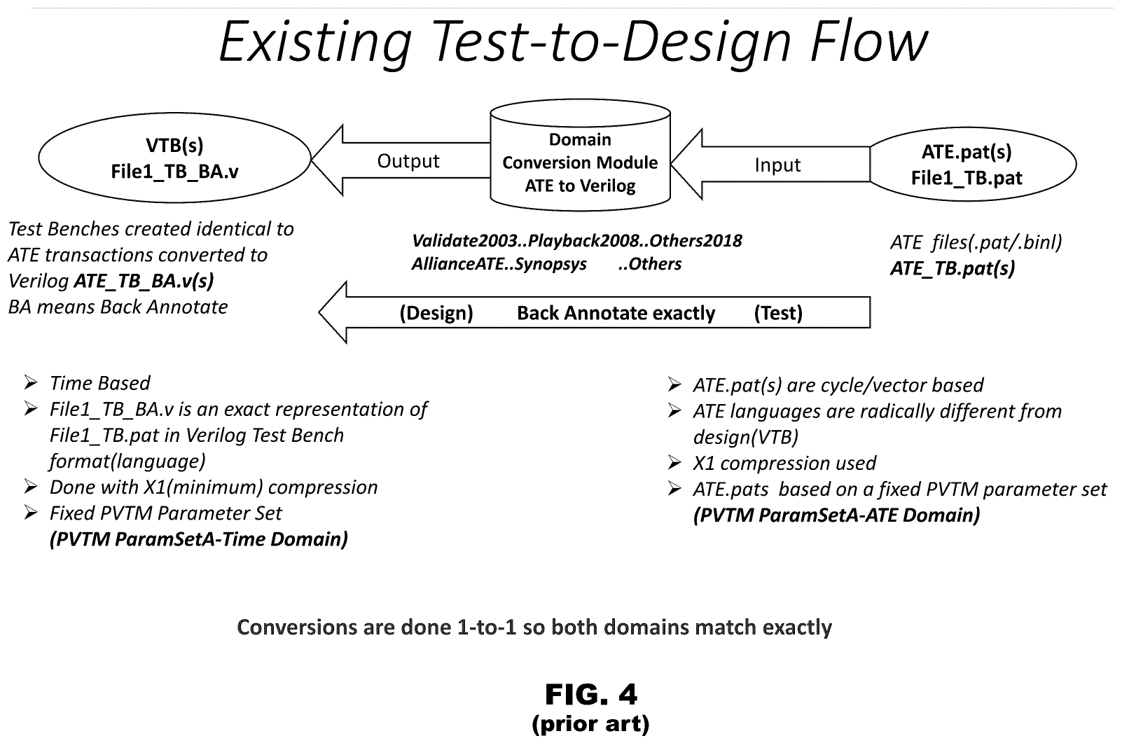

After ATE testing is completed, a subsequent stage in the methodology is to supply the ATE test results to the design process. FIG. 4 illustrates a flowchart of an illustrative methodology for a conversion of the testing pattern to a test vector file by the use of a domain conversion module.

As discussed above, the ATE.pat files are cycle/vector-based and derived from a fixed PVTM parameter set. By use of the domain conversion module, File1_TB_BA.v is generated as an exact representation of File1_TB.pat in Verilog Test Bench format language. The process is typically performed using X1 compression. Conversions can be done 1-to-1 so both domains match exactly.

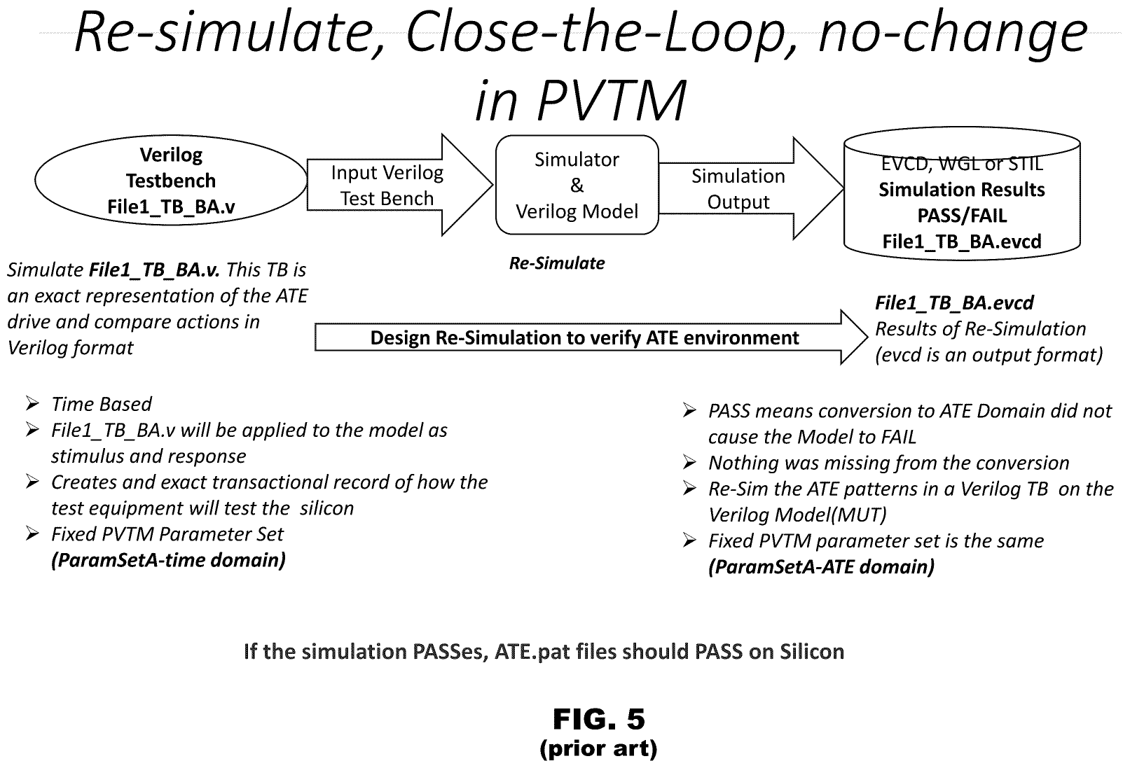

FIG. 5 illustrates a flowchart of an illustrative methodology for a further re-simulation of an electronic circuit, chip, or module by use of a simulator module. In some embodiments, the conversion of FIG. 5 follows further design refinements implemented on the design model.

In contrast to conventional techniques, the computer product and process described herein provides full automation by the margining of parameters during conversion between domains and creating equivalent Design and Test margined setup files with predicted results. This allows the converted files to be automatically run without GUI, human interaction or ATE Simulation/Emulation Model, thus significantly improving the efficiency on and engineering design, characterization, and release to manufacturing process.

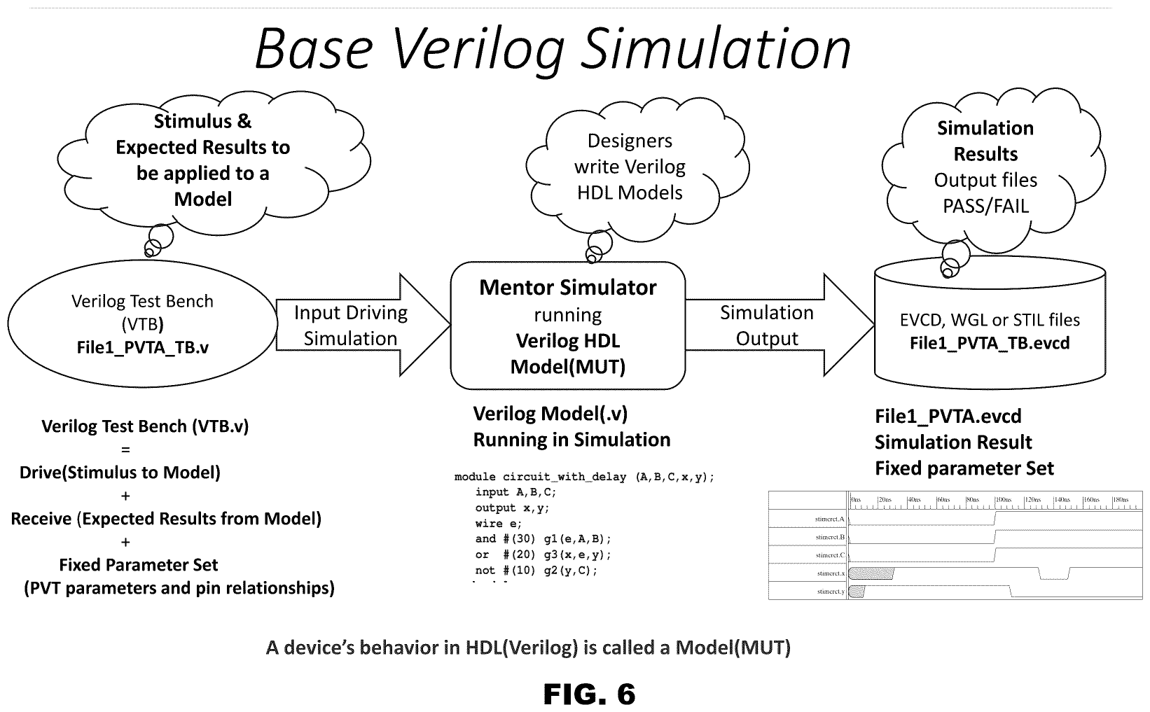

FIG. 6 is a block diagram of a flowchart of an illustrative methodology for simulation of an electronic circuit, chip, or module by use of a simulator module. A computer-implemented method for validating design of an electronic circuit includes a first step: receiving, at a processor, a device model defining an electronic circuit. The processor can be a single processor or a distributed processor. In some embodiments, Verilog HDL is used to describe the behavior of an integrated circuit, chip, or module in software.

A subsequent step in the method is performing, at the processor, logic simulation on the device model with use of a testbench using a set of operating parameters and producing a test vector file of event-based test vectors as a result of the logic simulation. VTB is a subset of the Verilog Language used to apply stimulus (inputs) and compare results (outputs) of a Verilog Model running in a simulator. Performing the logic simulation includes creating a VCD (Value Change Dump of Verilog) file as the test vector file. A simulator module is a software environment where a Verilog HDL Model (MUT) can be run by applying Test Benches (e.g., time stamp actions representing drives and compares in sequential time on pins: CLK 1@ #10 ns, CLK 0@ #21 ns). The simulation output results (typically expressed in an .evcd, .wgl. or .stil file) predicts the operation of the circuit under a fixed parameter set and whether it meets desired operation characteristics, e.g., a “pass” or a “fail.” The simulation module is run using a fixed parameter set, sometimes referred to as PVTM for process, voltage, temperature, timing or other parameters.

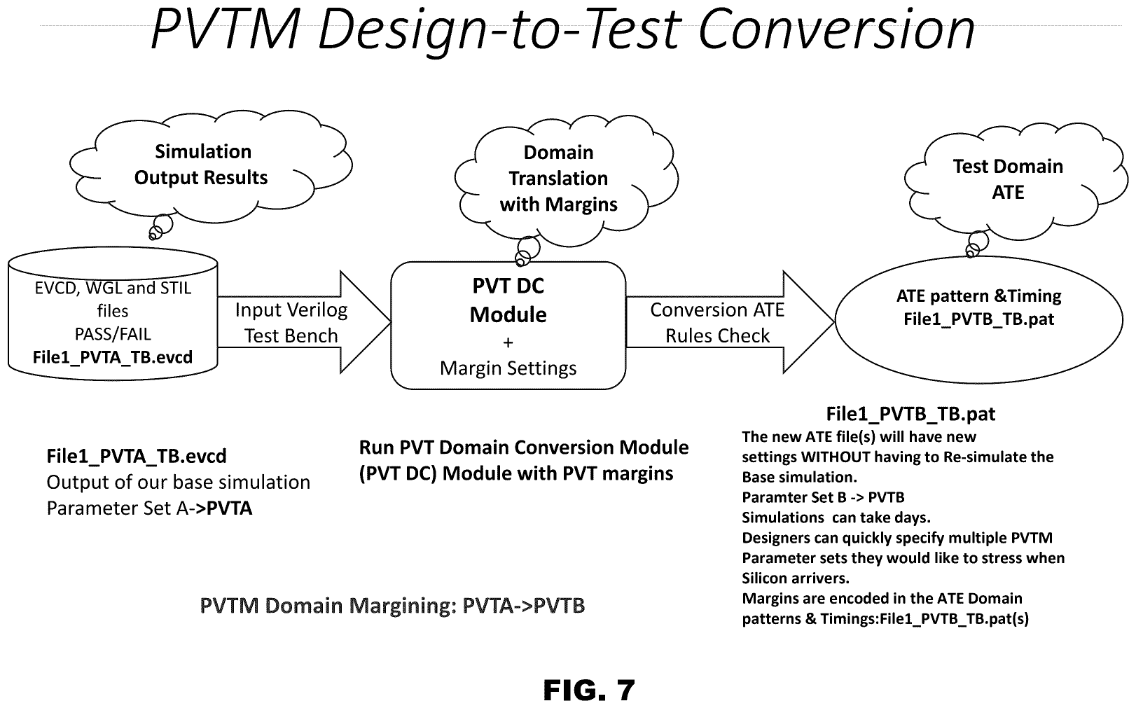

FIG. 7 is a flowchart of an illustrative methodology for the conversion of the output results parameter set, e.g., a test vector file, by the use of a PVT domain conversion (PVT DC) module in accordance with the disclosed subject matter to generate a test pattern for testing the electronic circuit on ATE.

A subsequent step in the process is receiving, at the processor, a model of the analog test equipment. A further step is converting, at the processor, the test vector file using the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model. In some embodiments, the testing patterns are cycle-based, and converting the test vector file involves converting the test vector file to a cycle-based test pattern. The PVT DC module converts the test vector file based at least in part upon the model of the ATE by varying one or more of the operating parameters over a range of values into a test pattern for testing the electronic circuit. The operating parameters are input stimuli of the electronic circuit, including, e.g., voltage, temperature, timing offsets and noise. Varying one or more of the operating parameters over a range of values includes applying values of a parameter incremented above and below an expected nominal value. Thus, in accordance with the computer product and process described herein, the PVT DC module is run with the PVT margins to generate and ATE test pattern. The new ATE files will have new setting without having to re-simulate the base simulation. Designers can specify multiple PVTM parameter sets to be tested (stressed) when the physical (DUT) arrives. As a result of running the PVT DC module, the margins are encoded in the ATE domain Once the ATE testing pattern is obtained, the DUT is tested on the ATE to determine whether the DUT, when manufactured using real-world processes, operates as predicted by the design.

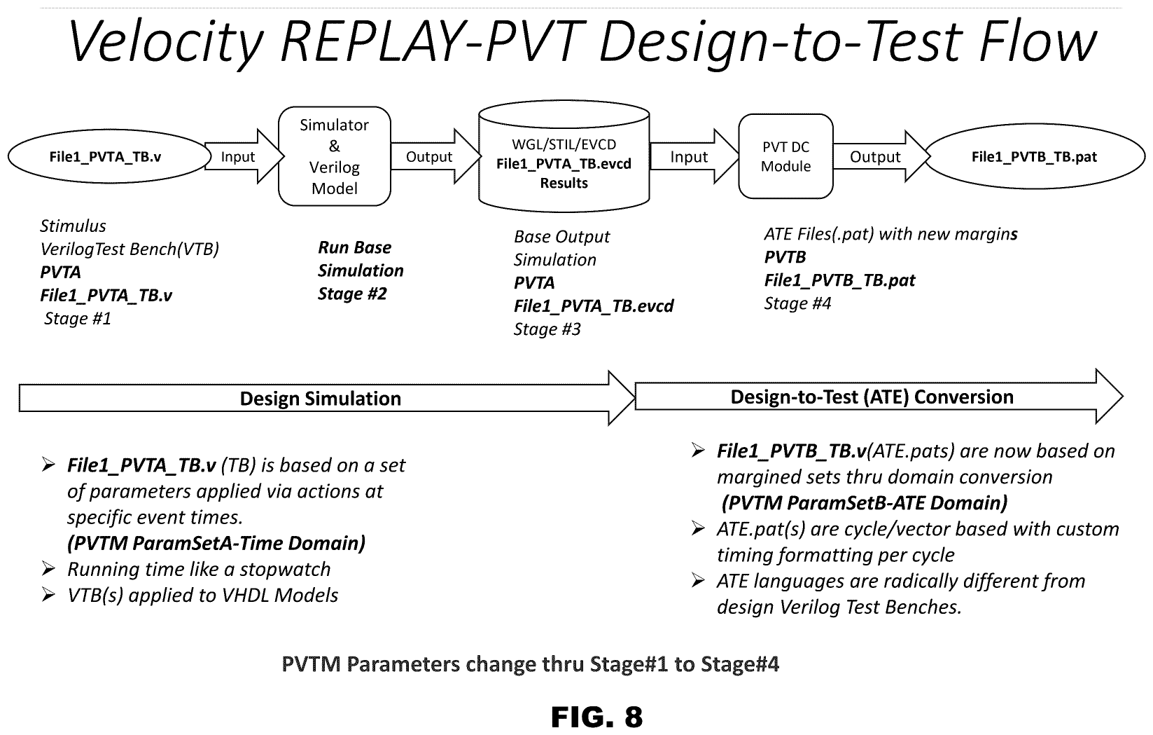

FIG. 8 is a flowchart of an illustrative methodology for simulation of an electronic circuit to derive simulation output results and conversion of simulation output results by the use of a PVT DC module to a test pattern for testing the electronic circuit. FIG. 8 captures the processes described above in FIGS. 6 and 7 in a sequence. The stimulus test bench (TB) is based on a set of fixed parameters applied via actions at specific event times. The Verilog TB(s) drive simulations: File1_PVTA_TB.v(s). The ATE test pattern (e.g., File1_PVTS_TB.pat) generated by the PVT DC module is now based on margined sets through domain conversion.

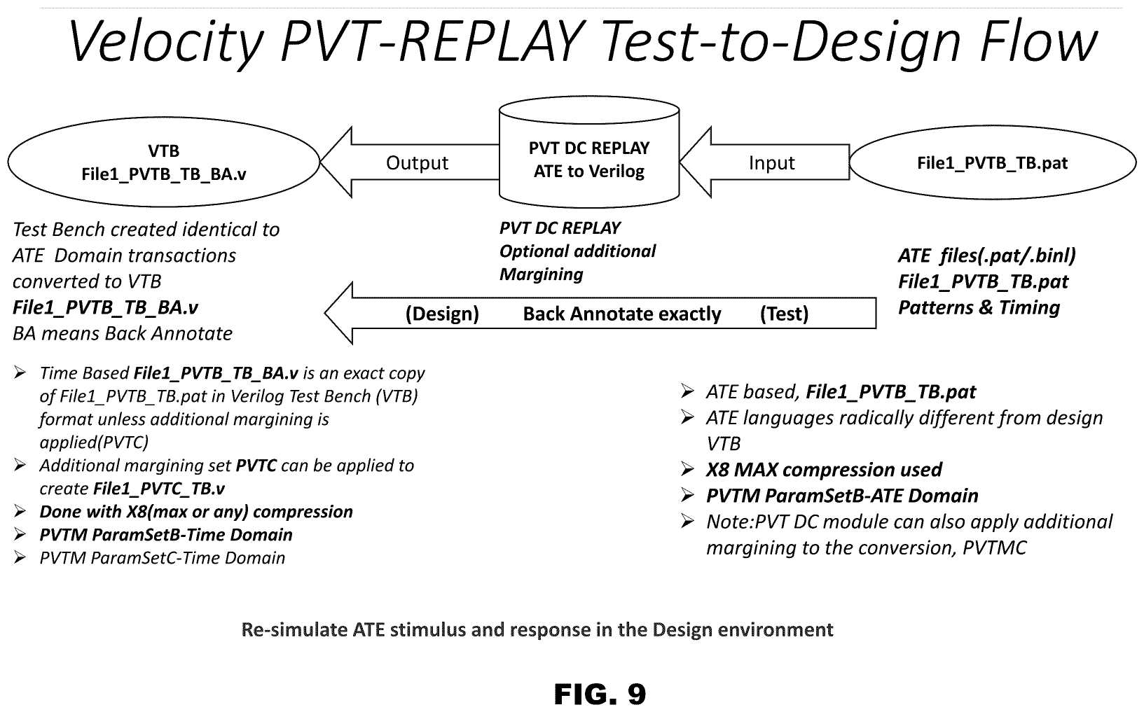

After ATE testing is completed, a subsequent stage in the methodology is to supply the ATE test results to the design process. FIG. 9 illustrates a flowchart of an illustrative methodology for a conversion of the testing pattern to a test vector file by the use of a PVT DC module.

As discussed above, the ATE.pat files are cycle/vector-based and derived from a fixed PVTM parameter set. By use of a PVT DC replay module, File1_PVTB_TB_BA.v is generated as an exact representation of File1_PVTB_TB.pat in Verilog Test Bench format language. The process is typically performed using X8 MAX compression. Conversions are done 1-to-1 so both domains match exactly. During the process shown in FIG. 9, an additional margining set PVTC can be applied to create File1_PVTC_TB.v.

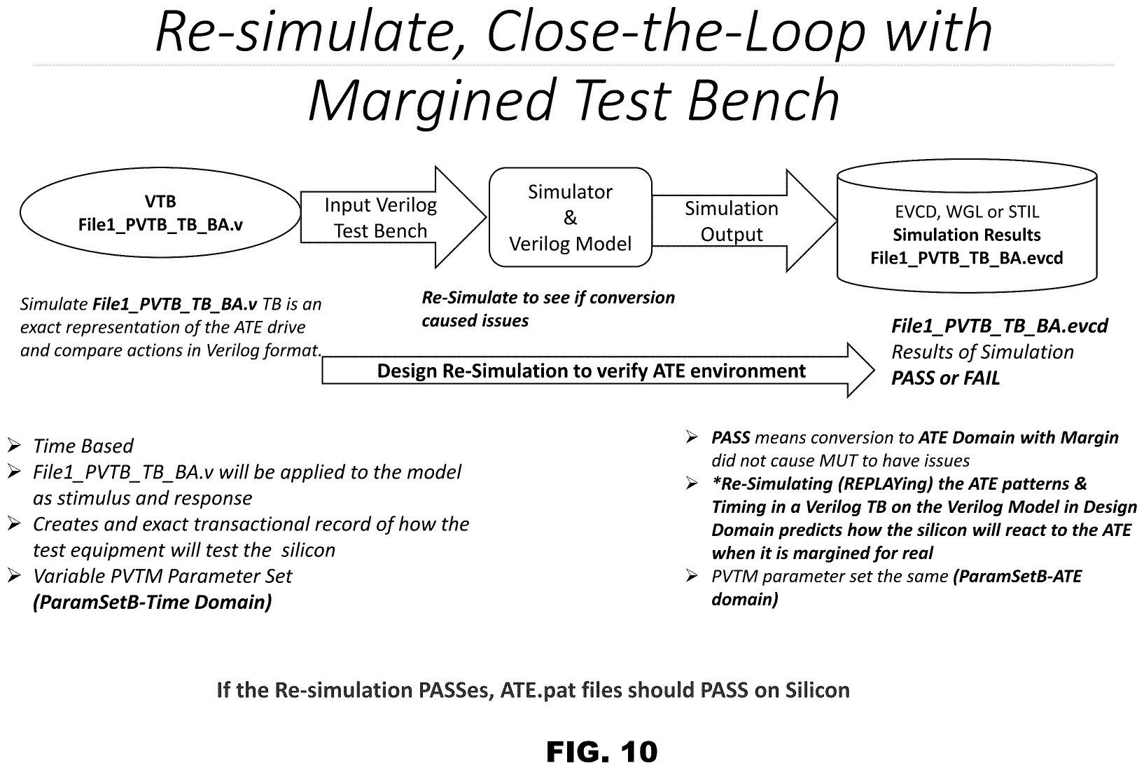

FIG. 10 illustrates a flowchart of an illustrative methodology for a further re-simulation of an electronic circuit, chip, or module by use of a simulator module. In some embodiments, the conversion of FIG. 10 follows further design refinements implemented on the design model.

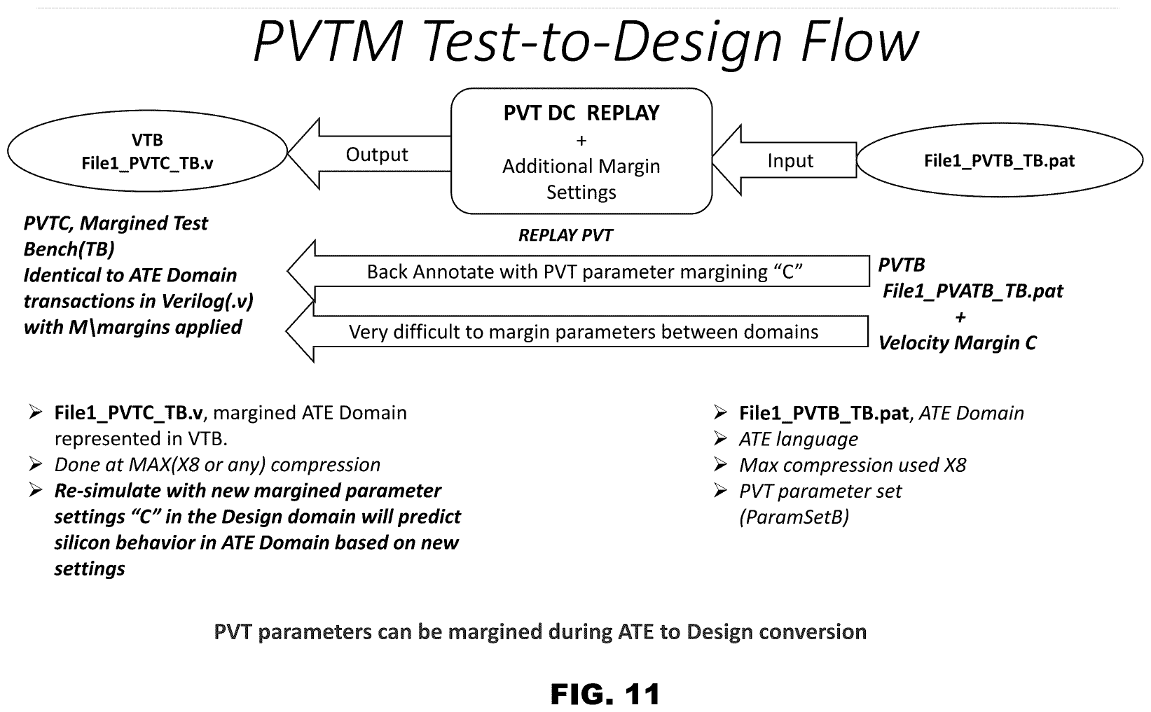

FIG. 11 illustrates a flowchart of an illustrative methodology for a conversion of the testing pattern to a test vector file by the use of a PVT DC module.

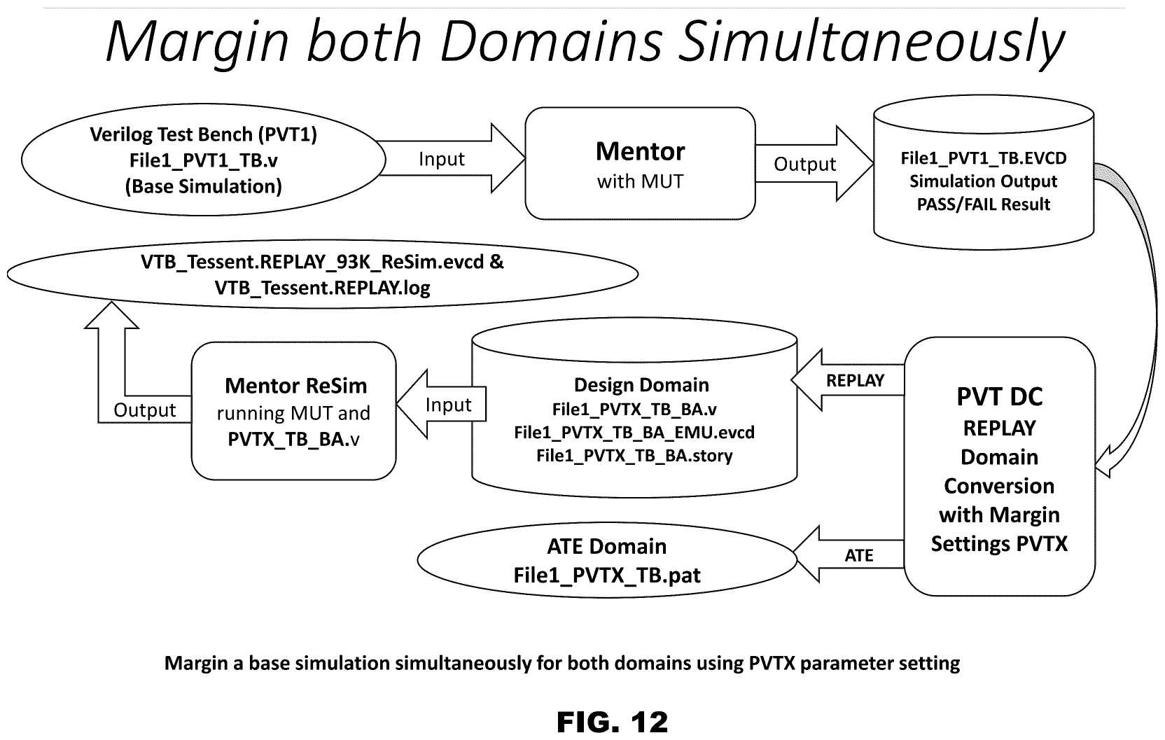

FIG. 12 illustrates a flowchart of an illustrative methodology for margining a base simulation simultaneously for both domains using PVTX parameter setting Margining parameters between domains with re-simulation allows a user to predict how conditions in one domain will react/affect those margined or stress conditions in another domain. Margining during conversion between domains eliminates complex ATE Verilog HDL models interacting with a domain (Design or Test). Using Parametric Set Margining during domain conversion allows immediate direct feedback thru the Verilog Test Bench or ATE.pat files without introducing another source of error from complex ATE VHDL Model. Velocity encodes the margin in the stimulus & result files, VTB or PAT of the other domain during the domain translation.

The goal has always been First Time Right (FTR), so that when silicon arrives, the manufactured electronic circuit operates as predicted the first time. Simulations are always available well before silicon arrives. Translating traditional performed margining techniques that are usually done in the ATE domain back to the Design-Time Domain will detect weak test conditions in the Design effectively predicting what will fail when silicon arrives and is tested on the ATE.

The computer product and process herein was specifically designed to simultaneously understand both domains and has IP and data structures design for domain transfer margining. From a base simulation, it is possible to simultaneously generate the new margined input Verilog Test Bench for re-simulation and the ATE equivalent files for silicon test. This significantly optimizes the back annotation process. Both domains can be margined at one time (one tool, one pass).

As used herein, the term “automatically,” and the logical and/or linguistic relatives and/or derivatives, mean that certain events and/or actions can be triggered and/or occur without any human intervention. In some embodiments, events and/or actions in accordance with the present disclosure can be in real-time and/or based on a predetermined periodicity of at least one of: nanosecond, several nanoseconds, millisecond, several milliseconds, second, several seconds, minute, several minutes, hourly, several hours, daily, several days, weekly, monthly, etc.

The material disclosed herein may be implemented in software or firmware or a combination of them or as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, etc.).

Implementations consistent with principles of the disclosure are not limited to any specific combination of hardware circuitry and software. For example, various embodiments may be embodied in many different ways as a software component such as, without limitation, a stand-alone software package, a combination of software packages, or it may be a software package incorporated as a “tool” in a larger software product.

The aforementioned examples are, of course, illustrative and not restrictive. While one or more embodiments of the present disclosure have been described, it is understood that these embodiments are illustrative only, and not restrictive, and that many modifications may become apparent to those of ordinary skill in the art, including that various embodiments of the inventive methodologies and the illustrative systems described herein can be utilized in any combination with each other. Further still, the various steps may be carried out in any desired order (and any desired steps may be added and/or any desired steps may be eliminated).

What is claimed is:

1. A computer-implemented method for validating design of an electronic circuit comprising the steps of:
receiving, at a processor, a device model defining an electronic circuit;
performing, at the processor, logic simulation on the device model with use of a testbench using a set of operating parameters and producing a test vector file of event-based test vectors as a result of the logic simulation;
receiving, at the processor, at least one model of the analog test equipment; and
converting, at the processor, the test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model.

2. The computer-implemented method of claim 1, wherein the operating parameters are input stimuli of the electronic circuit comprising at least one of voltage, temperature, timing offsets and noise.

3. The computer-implemented method of claim 1, wherein varying one or more of the operating parameters over a range of values comprising applying values of a parameter incremented above and below an expected nominal value.

4. The computer-implemented method of claim 1, wherein performing the logic simulation includes creating a VCD (Value Change Dump of Verilog) file as the test vector file.

5. The computer-implemented method of claim 1, wherein the testing patterns are cycle-based, and wherein converting the test vector file comprises converting the test vector file to a cycle-based test pattern.

6. The computer-implemented method of claim 1, wherein the device model is represented in Verilog Hardware Description language (HDL).

7. The computer-implemented method of claim 1, wherein the test vector files is one of EVCD, WGL or STIL formats.

8. The computer-implemented method of claim 1, wherein the processor is a single processor or a distributed processor.

9. A computer-implemented method for validating design of an electronic circuit comprising the steps of:
receiving, at a processor, a device model defining an electronic circuit;
performing, at the processor, logic simulation on the device model with use of a testbench using a set of operating parameters and producing a first test vector file of event-based test vectors as a result of the logic simulation;
receiving, at the processor, at least one model of the analog test equipment;
converting, at the processor, the first test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced using the device model;
executing the test pattern on the physical electronic circuit on the physical testing equipment by running the tester hardware; and
converting, at the processor, the test pattern by varying one or more of the operating parameters over a range of values into a second test vector file of event-based test vectors.

10. The computer-implemented method of claim 9, wherein the operating parameters are input stimuli of the electronic circuit comprising at least one of voltage, temperature, timing offsets and noise.

11. The computer-implemented method of claim 9, wherein varying one or more of the operating parameters over a range of values comprising applying values of a parameter incremented above and below an expected nominal value.

12. The computer-implemented method of claim 9, wherein performing the logic simulation includes creating a VCD (Value Change Dump of Verilog) file as the test vector file.

13. The computer-implemented method of claim 9, wherein the testing patterns are cycle-based, and wherein converting the test vector file comprises converting the test vector file to a cycle-based test pattern.

14. The computer-implemented method of claim 9, wherein the device model is represented in Verilog Hardware Description language (HDL).

15. The computer-implemented method of claim 9, wherein the test vector files is one of EVCD, WGL or STIL formats.

16. The computer-implemented method of claim 9, wherein the processor is a single processor or a distributed processor.

17. The computer-implemented method of claim 9, after executing the test pattern, further comprising comparing an observed output from the physical electronic circuit with an expected output from the test pattern.

18. The computer-implemented method of claim 17, further comprising identifying defects in the operation of the electronic circuit.

19. A computer program product for validating design of an electronic circuit, the computer program product comprising a computer readable medium tangibly embodying non-transitory computer-executable program instructions thereon that, when executed, cause one or more computing devices to:
receive a device model defining an electronic circuit;
perform logic simulation on the device model with use of a testbench using a set of operating parameters and producing a first test vector file of event-based test vectors as a result of the logic simulation;
receive at least one model of the analog test equipment; and
convert the first test vector file based at least in part upon the model of the analog test equipment by varying one or more of the operating parameters over a range of values into a test pattern for testing the electronic circuit, wherein the test patterns are configured to run on physical testing equipment having tester hardware for testing a physical electronic circuit produced by using the device model.

20. The computer program product of claim 19, wherein the non-transitory computer-executable program instructions, when executed, further cause one or more computing devices to convert the test pattern by varying one or more of the operating parameters over a range of values into a second test vector file of event-based test vectors.
